(19) United States
(12) Patent Application Publication
(10) Pub. No.: US 2025/0323130 A1
(43) Pub. Date: Oct. 16, 2025

(54) Wafer-Level Bond-Line Control

(71) Applicant: Wolfspeed, Inc., Durham, NC (US)

(72) Inventors: Chad O'Neal, Springdale, AR (US); Thomas Edgar Harrington, III, Carrollton, TX (US); Afshin Dadvand, Durham, NC (US); Devarajan Balaraman, Apex, NC (US)

(21) Appl. No.: 19/248,969

(22) Filed: Jun. 25, 2025

Related U.S. Application Data
(63) Continuation-in-part of application No. 18/419,128, filed on Jan. 22, 2024.
Application No. 18/419,128 is a continuation-in-part of application No. 18/358,616, filed on Jul. 25, 2023.

(51) Int. Cl. H01L 23/495; H01L 23/00

(52) U.S. Cl. CPC H01L 23/49562; H01L 24/13; H01L 24/16; H01L 24/32; H01L 24/48; H01L 24/73; H01L 24/94; H01L 2224/13013; H01L 2224/13014; H01L 2224/16225; H01L 2224/16245; H01L 2224/32057; H01L 2224/32225; H01L 2224/32245; H01L 2224/48245; H01L 2224/73204; H01L 2224/73257; H01L 2224/73265; H01L 2224/94; H01L 2924/12032; H01L 2924/13055; H01L 2924/13091

(57) ABSTRACT

Example aspects of the present disclosure are directed to power semiconductor device packages and methods of forming the same. In one example, a power semiconductor device package includes a submount, a semiconductor die on the submount, a die-attach material coupling the semiconductor die to the submount, and a housing formed around at least a portion of the submount and the semiconductor die. The semiconductor die includes a semiconductor structure, a metallization structure on a major surface of the semiconductor structure, and one or more support structures on the metallization structure. In one example, the die-attach material is provided around the one or more support structures between the semiconductor die and the submount.

### PRIORITY CLAIM

This application is a continuation-in-part of and claims the benefit of priority to U.S. patent application Ser. No. 18/419,128, having a filing date of Jan. 22, 2024, which is a continuation-in-part of and claims the benefit of priority to U.S. patent application Ser. No. 18/358,616, having a filing date of Jul. 25, 2023, the disclosures of which are incorporated herein by reference in their entireties and for all purposes.

### FIELD

The present disclosure relates generally to semiconductor devices.

### BACKGROUND

Semiconductor devices, including power semiconductor devices based on wide bandgap materials, may be formed on a semiconductor wafer as part of a semiconductor fabrication process. The semiconductor wafer may be diced into many individual pieces, each containing one or more semiconductor devices. Each of these pieces may be a semiconductor die. The semiconductor die may need to be attached to other components as part of packaging of the semiconductor device. For instance, a semiconductor die, such as a wide bandgap semiconductor die, may need to be attached to a conductive lead frame for use in a discrete power semiconductor package or a power module. Materials used to attach the semiconductor die to other components may need to provide a thermal, mechanical, and/or electrical connection of the semiconductor die to the other components.

### SUMMARY

Aspects and advantages of embodiments of the present disclosure will be set forth in part in the following description, or can be learned from the description, or can be learned through practice of the embodiments.

One example aspect of the present disclosure is directed to a semiconductor die. The semiconductor die includes a semiconductor structure, a metallization structure on a major surface of the semiconductor structure, and one or more support structures on the metallization structure.

Another example aspect of the present disclosure is directed to a power semiconductor device package. The power semiconductor device package includes a submount. The power semiconductor device package further includes a semiconductor die. The semiconductor die includes a semiconductor structure, a metallization structure on a major surface of the semiconductor structure, and one or more support structures on the metallization structure. The power semiconductor device package further includes a die-attach material around the one or more support structures between the semiconductor die and the submount, the die-attach material coupling the semiconductor die to the submount.

Another example aspect of the present disclosure is directed to a method. The method includes providing a semiconductor wafer comprising a semiconductor structure. The method further includes providing a metallization structure on a major surface of the semiconductor structure. The method further includes forming a plurality of support structures on the metallization structure. The method further includes dicing the semiconductor wafer into a plurality of semiconductor die, each semiconductor die comprising at least one support structure.

Another example aspect of the present disclosure is directed to a power semiconductor device package. The power semiconductor device package includes a submount. The power semiconductor device package further includes a semiconductor die on the submount. The semiconductor die includes a semiconductor structure, a metallization structure on a bottom surface of the semiconductor structure, and a plurality of support structures on the metallization structure. The power semiconductor device package further includes a die-attach material coupling the semiconductor die to the submount. The power semiconductor device package further includes a housing comprising an encapsulating material formed around at least a portion of the submount and the semiconductor die.

Another example aspect of the present disclosure is directed to a semiconductor die. The semiconductor die includes a semiconductor structure, a source metallization structure on a top surface of the semiconductor structure, a drain metallization structure on a bottom surface of the semiconductor structure, one or more first support structures on the source metallization structure, and one or more second support structures on the drain metallization structure.

Another example aspect of the present disclosure is directed to a power semiconductor device package. The power semiconductor device package includes a first submount, a second submount, and one or more support structures contacting the first submount and the second submount such that the one or more support structures are between the first submount and the second submount.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts a plan view of an example semiconductor wafer according to example embodiments of the present disclosure;

FIG. 2 depicts a plan view of an example semiconductor die formed from an example semiconductor wafer according to example embodiments of the present disclosure;

FIG. 3 depicts a plan view of an example semiconductor die formed from an example semiconductor wafer according to example embodiments of the present disclosure;

FIGS. 4A-4C depict cross-sectional views of an example power semiconductor device package according to example embodiments of the present disclosure;

FIG. 5 depicts a cross-sectional view of an example power semiconductor device package according to example embodiments of the present disclosure;

FIGS. 6A-6C depict cross-sectional plan views of an example support structure according to example embodiments of the present disclosure;

FIG. 7 depicts a cross-sectional view of an example power semiconductor device package according to example embodiments of the present disclosure;

FIG. 8 depicts a cross-sectional view of an example power semiconductor device package according to example embodiments of the present disclosure;

FIGS. 9A-9B depict plan views of an example semiconductor die according to example embodiments of the present disclosure;

FIG. 10 depicts a cross-sectional view of an example power semiconductor device package according to example embodiments of the present disclosure;

FIG. 11 depicts a flow chart diagram of an example method according to example embodiments of the present disclosure;

FIG. 12 depicts an exploded, perspective view of an example semiconductor package with an example stud protrusion configuration on a semiconductor die according to example embodiments of the present disclosure;

FIG. 13 depicts an example semiconductor package of a semiconductor device according to example embodiments of the present disclosure; and

FIG. 14 depicts an example semiconductor package of a semiconductor device according to example embodiments of the present disclosure.

Repeat use of reference characters in the present specification and drawings is intended to represent the same and/or analogous features or elements of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations may be made to the embodiments without departing from the scope or spirit of the present disclosure. For instance, features illustrated or described as part of one embodiment may be used with another embodiment to yield a still further embodiment. Thus, it is intended that aspects of the present disclosure cover such modifications and variations.

Semiconductor device packages, such as power semiconductor device packages (e.g., discrete power semiconductor device packages, power modules, etc.), have been developed that include a semiconductor die (e.g., semiconductor die). In some examples, such semiconductor die include one or more semiconductor devices, such as a metal-oxide-semiconductor field-effect transistor (MOSFET), a Schottky diode, an insulated gate bipolar transistor (IGBT), and/or a high electron mobility transistor (HEMT) device. Power semiconductor device packages with MOSFETs may be employed in a variety of applications to enable higher switching frequencies along with reduced associated losses, higher blocking voltages, and improved avalanche capabilities. Example applications may include high performance industrial power supplies, server/telecom power, electric vehicle charging systems, energy storage systems, uninterruptible power supplies, high-voltage DC/DC converters, electric vehicles, and battery management systems. Power semiconductor device packages with Schottky diodes and/or HEMT devices may be employed in many of the same high-performance power applications described above with respect to MOSFETs. In some examples, power semiconductor device packages with Schottky diodes may be employed in systems that also include power semiconductor device packages with MOSFETs.

Example aspects of the present disclosure are directed to power semiconductor device packages (e.g., discrete power semiconductor device packages, power modules, etc.) for use in semiconductor applications and other electronic applications. It should be understood that the terms “semiconductor device package,” “semiconductor package,” “power semiconductor device package,” and/or “power semiconductor package” may be used interchangeably. In some examples, semiconductor device packages may include one or more semiconductor die. The one or more semiconductor die may include a wide bandgap semiconductor material. A wide bandgap semiconductor has a band gap greater than about 1.40 eV, such as silicon carbide (SiC) and/or a Group III-nitride (e.g., gallium nitride).

In some examples, the one or more semiconductor die may include one or more semiconductor devices, such as transistors, diodes, thyristors, and/or the like. It should be understood that the terms “semiconductor device(s)” and/or “power semiconductor device(s)” may be used interchangeably. For instance, in some examples, the one or more semiconductor die may include a metal-oxide-semiconductor field-effect transistor (MOSFET), such as a silicon carbide-based MOSFET. Additionally and/or alternatively, in some examples, the one or more semiconductor die may include a Schottky diode, such as a silicon carbide-based Schottky diode. In such examples, the Schottky diode(s) may be located between a first (e.g., cathode) lead and a second (e.g., anode) lead of a power semiconductor device package to form, for instance, a vertical structure power semiconductor device. Additionally and/or alternatively, in some examples, the one or more semiconductor die may include a HEMT device, such as a Group-III nitride-based HEMT device. Additionally and/or alternatively, in some examples, the one or more semiconductor die may include an insulated gate bipolar transistor (IGBT), such as a wide bandgap semiconductor material-based IGBT.

It should be understood that aspects of the present disclosure are discussed with reference to silicon carbide-based MOSFET devices and silicon carbide-based Schottky diode devices for purposes of illustration and discussion. Those having ordinary skill in the art, using the disclosures provided herein, will understand that the power semiconductor device packages of the present disclosure may include other power semiconductor devices without deviating from the scope of the present disclosure, such as, by way of non-limiting example, diodes (e.g., PiN diodes, etc.), insulated gate bipolar transistors, HEMTs, and/or other devices. Furthermore, it should be understood that aspects of the present disclosure are discussed with reference to vertical structure power semiconductor devices for purposes of illustration and discussion. Those having ordinary skill in the art, using the disclosures provided herein, will understand that power semiconductor device packages of the present disclosure may include other forms of power semiconductor devices without deviating from the scope of the present disclosure, such as, by way of non-limiting example, horizontal or lateral power semiconductor devices and/or the like.

In some power semiconductor device packages, the one or more semiconductor die may be attached to a submount, such as a lead frame, a power substrate (e.g., direct bonded copper (DBC) substrate, active metal brazed (AMB) substrate, etc.), and/or the like, by a die-attach material between the one or more semiconductor die and the submount. For instance, in some examples, a die-attach material may be deposited on the submount, and the semiconductor die (and/or other component) may be placed on the die-attach material. The die-attach material may be subjected to bonding and/or a bonding process (e.g., sintering) to secure the semiconductor die (and/or other component) to the die-attach material. Various types of die-attach material may be used to bond the one or more semiconductor die to the submount such as, for instance, metal sintering die-attach (e.g., silver (Ag) or copper (Cu)) and conductive adhesive die-attach. Additionally and/or alternatively, in some examples, the power semiconductor device package may use wire bond(s), ribbon bond(s), and/or the like, for interconnection between portions of the one or more semiconductor die (e.g., a gate contact) and the package (e.g., lead frame). Furthermore, in some examples, a passivation layer may be provided on the one or more semiconductor die, such as a silicon nitride and/or polyimide passivation layer.

The power semiconductor device package may further include a housing in which the one or more semiconductor die may be arranged. More particularly, in some examples, the housing may be and/or may include an encapsulating material (e.g., epoxy mold compound (EMC), ceramic-based encapsulating material(s), silicon-based encapsulating material(s), polymer-based encapsulating material(s), etc.) formed around at least a portion of the submount and the one or more semiconductor die. The power semiconductor device package may also include one or more electrical leads extending from the housing. In some examples, the power semiconductor device package may include a plurality of electrical leads, each of which may extend from a same side of the housing relative to one another. Additionally and/or alternatively, in other examples, the power semiconductor device package may include a plurality of electrical leads, at least one of which may extend from a different side of the housing relative to the other electrical leads. It should be understood that, as used herein, a “plurality of electrical leads” includes at least two, or more, electrical leads extending from the housing.

The power semiconductor device package may further include one or more metallization structures. A “metallization structure” is any layer, structure, or other portion of a semiconductor die that incorporates a metal for thermal and/or electrical conduction. Metallization structures in a semiconductor device may be used, for instance, to provide an electrically conductive and/or thermally conductive connection to the one or more semiconductor die. The metallization structure may include, for instance, one or more electrodes, contacts, interconnections, bonding pads, backside layers, metal layers, or metal coatings of the semiconductor device on the semiconductor die.

The various technologies that are practiced in the semiconductor industry for die-attach present a variety of challenges and limitations. For instance, the uniformity, performance, and reliability of the die-attach material may be adversely affected during the bonding process. In addition, semiconductor packages may experience anomalies and/or failures resulting from deformation, delamination, shifting, moving (e.g., glacial moving), and/or the like, of the various components of the semiconductor package during the bonding process. These anomalies and/or failures may, in turn, affect the electrical, mechanical, and thermal properties of the resulting semiconductor package.

A variety of factors may affect whether these anomalies and/or failures arise during the semiconductor manufacturing process (e.g., the bonding process). Such factors affecting the uniformity, performance, and reliability of the resulting semiconductor package may include the die-attach material and bonding process used during the semiconductor manufacturing process. In addition, the design and structure of the semiconductor die and the submount may likewise affect the uniformity, performance, and reliability of the die-attach itself. Thus, in addition to the chosen die-attach material, the design and structure of the semiconductor die and the submount themselves may play an important role in the bonding process.

Solutions for reducing the anomalies and/or failures that may arise during the semiconductor manufacturing process may include die-attach material selection, process controls (e.g., dispense volume, dispense pattern, die-bond parameters), the design and structure of the submount, the design and structure of the semiconductor die, and/or the like.

Accordingly, example aspects of the present disclosure are directed to a semiconductor package having a submount that defines a base plane. The semiconductor package may further include a semiconductor die on the submount. In some examples, a die-attach film with prefabricated stud protrusion(s) may be placed on a bottom surface of the semiconductor die (e.g., surface facing the submount) prior to depositing the die-attach material. Furthermore, the prefabricated stud protrusion(s) may be printed stud protrusion(s). For instance, in some embodiments, the prefabricated stud protrusion(s) may be formed by, e.g., inkjet printing. More specifically, droplets of a polymer, such as, e.g., Poly(4-vinylphenol), may be deposited on a semiconductor die at certain distances. Additionally and/or alternatively, droplets of the polymer (e.g., Poly(4-vinylphenol)) may be deposited on a die-attach film, which is subsequently transferred to the semiconductor die. Various parameters (e.g., height, diameter) may be optimized to ensure the droplets and/or stud protrusion(s) are uniformly distributed.

Furthermore, the stud protrusion(s) may include a planar surface, and the semiconductor die may be on the planar surface of the stud protrusion(s). In some embodiments, the planar surface of the stud protrusion(s) may include a circular cross-section, square cross-section, or other suitable shape cross-section. In addition, the submount may include stud protrusion(s) in a center portion of the semiconductor die, in a peripheral portion of the semiconductor die, and/or both.

As used herein, a “peripheral portion” of the semiconductor die includes regions of a surface of the semiconductor die that are closer to a perimeter of the surface of the semiconductor die relative to a geometric center of surface of the semiconductor die. A “center portion” of the semiconductor die includes regions of the semiconductor die that are closer to a geometric center of the semiconductor die relative to a perimeter of the semiconductor die.

Example aspects of the present disclosure are further directed to a die-attach process to control and increase uniformity, performance, and reliability of semiconductor packages. The die-attach process may include placing a semiconductor die on a submount. The die-attach process may further include attaching the semiconductor die to the submount with a die-attach material. In some embodiments, the semiconductor die may be attached to the submount by sintering the die-attach material. In other embodiments, an electroless deposition process may be performed to deposit an electroless deposited material to attach the semiconductor die to the submount. In this way, the design and structure of the submount and/or the semiconductor die may allow for a variety of different bonding processes and die-attach materials to be used without adversely affecting the uniformity, performance, and reliability of the resulting semiconductor package.

Aspects of the present disclosure are discussed with reference to a die-attach material for attaching a semiconductor die (e.g., a silicon carbide-based semiconductor die, Group III nitride-based semiconductor die, silicon-based semiconductor die, etc.) to a substrate or other component for purposes of illustration and discussion. Those of ordinary skill in the art, using the disclosures provided herein, will understand that the materials provided herein may be used to provide attachment of any suitable components without deviating from the scope of the present disclosure. In this regard, the term “die-attach material” in the disclosure and in the claims is intended to refer to any material that is used to provide thermal, electrical, and/or mechanical connection between two components.

Furthermore, as used herein, “bonding” or “bonding process” refers to causing a transition of a material from a first form to a second form. A bonding process may or may not require attaching a component to the material. Sintering, adhesion, deposition, reflow, annealing, curing, exposing to light, and exposing to ultraviolet light are examples of bonding processes and are encompassed by the term “bonding” or “bonding process” in the disclosure and in the claims.

Example aspects of the present disclosure are further directed to power semiconductor device packages having integrated bond-line support structure(s) that are operable to provide optimized and consistent bond-line thickness and bond-line uniformity. As used herein, “bond-line thickness (BLT)” refers to a vertical thickness of the attach layer (e.g., die-attach material) used to bond the internal components of power semiconductor device packages, such as the vertical thickness of the die-attach material used to couple a semiconductor die to an underlying submount. Additionally, “bond-line uniformity (BLU)” refers to a consistency and/or uniformity of the “bond-line thickness” across the entire interface area between, for instance, the semiconductor die and the underlying submount.

More particularly, a power semiconductor device package of the present disclosure may include a submount (e.g., lead frame, power substrate, etc.), a semiconductor die on the submount, and a die-attach material coupling the semiconductor die to the submount. The semiconductor die may include a semiconductor structure (e.g., wide bandgap semiconductor structure) and a metallization structure (e.g., contact, electrode, etc.) on a major surface of the semiconductor structure. To reduce the anomalies and/or failures that may arise during the semiconductor manufacturing process, the semiconductor die may further include one or more support structures on the metallization structure that extend in a generally perpendicular direction away from the major surface of the semiconductor structure on which the metallization structure is arranged. The die-attach material may at least partially contact and/or conform around the one or more support structures (e.g., between the submount and the semiconductor die), thereby providing a bond-line thickness (BLT) that is substantially equal to a height of the one or more support structures.

As described in greater detail below, example power semiconductor device packages of the present disclosure may have a variety of different support-structure configurations. For instance, in some examples, a power semiconductor device package may include one or more support structures on a metallization structure that is arranged on a bottom surface of the semiconductor structure, such as a drain metallization structure (e.g., drain electrode). Additionally and/or alternatively, in some examples, a power semiconductor device package may include one or more support structures on a metallization structure that is arranged on a top surface of the semiconductor structure, such as one or more source metallization structures (e.g., source electrodes). Additionally and/or alternatively, in some examples, a power semiconductor device package may include one or more first support structures on a first metallization structure (e.g., arranged on the top surface of the semiconductor structure) and one or more second support structures on a second metallization structure (e.g., arranged on the bottom surface of the semiconductor structure).

Aspects of the present disclosure provide a number of technical effects and benefits. For instance, power semiconductor device packages having support structures integrated therein provide for greater control over the bond-line thickness and bond-line uniformity of the die-attach material of the power semiconductor device package. As such, example aspects of the present disclosure are operable to provide a power semiconductor device package having consistent electrical conductivity, thermal conductivity, and mechanical strength across the entire interface area between the semiconductor die and the underlying submount which, in turn, may provide improvement in device ampacity, power cycling, and thermal shock lifetime. Moreover, by incorporating support structures on one and/or both major surfaces of a semiconductor wafer prior to dicing the wafer into a plurality of semiconductor die, example aspects of the present disclosure provide a significant cost reduction at the module-assembly level. Additionally, by providing the support structures between the semiconductor die and the submount, the support structures are operable to apply pressure at the interface area during reflow and curing of the die-attach material, thereby ensuring proper attachment in power semiconductor device packages that bow and/or curve during the packaging process.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, structure, region, or substrate is referred to as being “on” or extending “onto” another element, it may be directly on or extend directly onto the other element or intervening elements may also be present and may be only partially on the other element. In contrast, when an element is referred to as being “directly on” or extending “directly onto” another element, there are no intervening elements present, and may be partially directly on the other element. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

As used herein, a first structure “at least partially overlaps” or is “overlapping” a second structure if an axis that is generally perpendicular to a major surface of the first structure passes through both the first structure and the second structure. A “peripheral portion” of a structure includes regions of a structure that are closer to a perimeter of a surface of the structure relative to a geometric center of the surface of the structure. A “center portion” of the structure includes regions of the structure that are closer to a geometric center of the surface of the structure relative to a perimeter of the surface. “Generally perpendicular” means within 15 degrees of perpendicular. “Generally parallel” means within 15 degrees of parallel.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the disclosure are described with reference to semiconductor layers and/or regions which are characterized as having a conductivity type such as n type or p type, which refers to the majority carrier concentration in the layer and/or region. Thus, n type material has a majority equilibrium concentration of negatively charged electrons, while p type material has a majority equilibrium concentration of positively charged holes. Some material may be designated with a “+” or “−” (as in n+, n−, p+, p−, n++, −−p++, p−−, or the like), to indicate a relatively larger (“+”) or smaller (“−”) concentration of majority carriers compared to another layer or region. However, such notation does not imply the existence of a particular concentration of majority or minority carriers in a layer or region.

Some embodiments of the disclosure are described with reference to a semiconductor structure. The semiconductor structure may or may not include an underlying substrate. As used herein, a “semiconductor structure” refers to a structure that includes one or more semiconductor layers, such as, for example, semiconductor substrates, semiconductor epitaxial layers, and/or the like. The semiconductor structure may have one or more layers and/or regions of a first conductivity type, one or more layers and/or regions having a second conductivity type, and/or any combination thereof. As used herein, the terms “first conductivity type” and “second conductivity type” are used to indicate either n-type or p-type, where the first conductivity type and the second conductivity type are different from one another. That is, if a first region/layer of a semiconductor device has a first conductivity type and a second region/layer of the semiconductor device has a second conductivity type, this means either that the first region/layer has n-type conductivity and the second region/layer has p-type conductivity or, alternatively, that the first region/layer has p-type conductivity and the second region/layer has n-type conductivity.

In the drawings and specification, there have been disclosed typical embodiments and, although specific terms are employed, they are used in a generic and descriptive sense only and not for purposes of limitation of the scope set forth in the following claims.

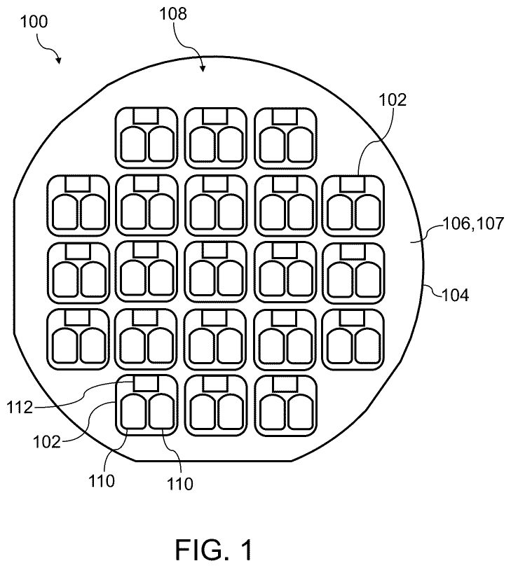

FIG. 1 depicts a plan view of a top side of an example semiconductor wafer 100 according to example embodiments of the present disclosure. The semiconductor wafer 100 may serve as the foundation for manufacturing a plurality of semiconductor devices, such as integrated circuits (ICs) and/or other electronic components. It should be understood that FIG. 1 is intended to represent structures for purposes of identification and description and is not intended to represent the structures to physical scale.

As shown, the semiconductor wafer 100 may include a plurality of power semiconductor devices 102 provided therein. The power semiconductor devices 102 may be provided in rows and columns and may be spaced apart from each other such that the semiconductor wafer 100 may later be subjected to a singulation process (e.g., diced) to separate the individual power semiconductor devices 102 for packaging and testing.

The semiconductor wafer 100 may be a thin, disc-shaped sheet of semiconductor material, such as silicon (Si), silicon carbide (SiC), gallium nitride (GaN), and/or the like. The semiconductor wafer 100 may include a semiconductor structure with other material layers, such as protective (e.g., passivation) layers and/or metal layers, provided thereon. More particularly, the semiconductor wafer 100 may include a semiconductor structure 104 (e.g., semiconductor substrate 104). It should be understood that the terms “semiconductor structure” and “semiconductor substrate” may be used interchangeably herein. In some examples, the semiconductor wafer 100 may include one or more epitaxial layers 106, which may be a single-crystal semiconductor layer grown on a top side of the semiconductor structure 104. In some examples, the semiconductor wafer 100 may include one or more passivation layers 107 having any suitable passivation material, such as one or more silicon nitride layers, one or more polymer layers, and/or the like.

The semiconductor structure 104 may include a semiconductor material, such as a wide bandgap semiconductor material. By way of non-limiting example, the semiconductor structure 104 may be a silicon (Si) substrate, a silicon carbide (SiC) substrate, a Group III-nitride (e.g., gallium nitride (GaN)) substrate, a sapphire substrate, and/or other suitable substrates. In some examples, the semiconductor structure 104 may be a SiC substrate that may include, for example, the 4H polytype of SiC or may be the 3C, 6H, and/or 15R polytypes of SiC. Other semiconductor layers (e.g., polysilicon gate layers), protective layers (e.g., passivation layers), insulating layers, and/or metal layers may be provided on the semiconductor structure 104 to form the plurality of power semiconductor devices 102. In this manner, the semiconductor structure 104 may be a semiconductor structure. As used herein, a “semiconductor structure” refers to a structure having one or more semiconductor layers, such as semiconductor substrates and/or semiconductor epitaxial layers.

As noted above, the semiconductor wafer 100 may be subjected to wafer-level processing and diced to form a plurality of semiconductor die 108 having one or more of the plurality of power semiconductor devices 102. More particularly, each power semiconductor device 102 may be spaced apart on the semiconductor wafer 100 and may include, for instance, a silicon carbide-based metal-oxide-semiconductor field-effect transistor (MOSFET), a silicon carbide-based Schottky diode, a Group-III nitride-based high electron mobility transistor (HEMT) device, an insulated gate bipolar transistor (IGBT), and/or the like. The semiconductor wafer 100 may be cut and/or diced (e.g., using a wire saw and/or a laser) along a portion of the semiconductor wafer 100 that runs between each of the power semiconductor devices 102 such that each individual cut piece becomes a semiconductor die 108 that is later packaged in a semiconductor device package (e.g., discrete semiconductor device package, power module, etc.).

In some examples, such as that depicted in FIG. 1, the power semiconductor devices 102 may include vertical structures (e.g., vertical semiconductor device units) such that each power semiconductor device 102 is a vertical semiconductor device. More particularly, each power semiconductor device 102 may include at least one electrode (e.g., source electrode, gate electrode, drain electrode for a power MOSFET device) on each major side (e.g., top side, bottom side) of the semiconductor structure. Additionally and/or alternatively, in other examples (not shown), the power semiconductor devices 102 may include lateral structures (e.g., lateral semiconductor device units) such that each power semiconductor device 102 is a lateral semiconductor device having the electrodes on the same major side of the semiconductor structure. Furthermore, metal layer structures (e.g., metallization layers and/or metallization structures) may be provided on each side of the power semiconductor devices 102 to form electrodes for the power semiconductor devices 102 (e.g., source electrode 110, gate electrode 112, drain electrode (not shown)). It should be understood that the terms “metal layer structure,” “metallization layer,” and/or “metallization structure” may be used interchangeably.

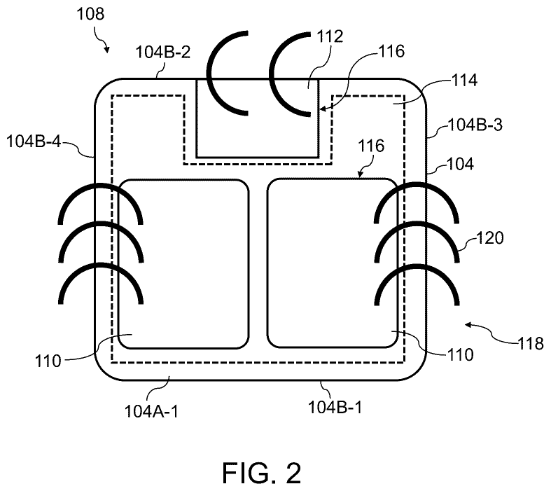

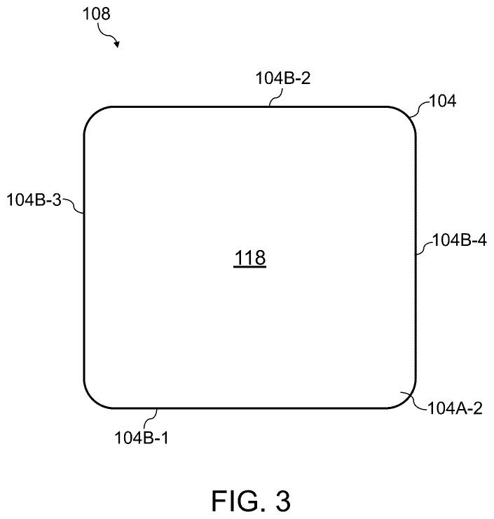

FIGS. 2-3 depict plan views of an example semiconductor die 108 formed from the example semiconductor wafer 100 depicted in FIG. 1 according to example embodiments of the present disclosure. More particularly, FIG. 2 depicts a top plan view of the example semiconductor die 108, and FIG. 3 depicts a bottom plan view of the example semiconductor die 108. As described herein, the semiconductor wafer 100 (FIG. 1) may be cut and/or diced along a portion of the semiconductor wafer 100 (FIG. 1) such that the semiconductor die 108 includes one or more of the plurality of power semiconductor devices 102. It should be understood that, in the description below, it is assumed that the semiconductor die 108 includes a power semiconductor device 102 that is an n-type power MOSFET. However, those having ordinary skill in the art, using the disclosures provided herein, will understand that aspects of the present disclosure may be implemented in a p-type power MOSFET and/or in other types of semiconductor devices (e.g., IGBT, Schottky diode, etc.) without deviating from the scope of the present disclosure. Furthermore, it should be understood that FIGS. 2-3 are intended to represent structures for purposes of identification and description and are not intended to represent the structures to physical scale.

As shown in FIGS. 2-3, the semiconductor die 108 may include a semiconductor substrate, such as the semiconductor structure 104. As described herein, the semiconductor structure 104 may include a wide bandgap semiconductor material, such as, by way of non-limiting example, silicon carbide (SiC), a Group III-nitride (e.g., gallium nitride (GaN)), and/or the like. The semiconductor structure 104 may include one or more surfaces and/or one or more sides. For instance, the semiconductor structure 104 may include one or more “major” surfaces 104A and one or more “minor” surfaces 104B. As described herein, a “major side(s)” and/or a “major surface(s)” refers to a primary (e.g., most significant) surface(s) of the semiconductor structure 104, such as the principal face(s) of the semiconductor structure 104, the side(s) having the largest surface area, and/or the like. Conversely, a “minor side(s)” and/or a “minor surface(s)” refers to a secondary (e.g., less prominent) surface(s) of the semiconductor structure 104 relative to the “major side(s),” such as the side surface(s) of the semiconductor structure 104, the side(s) having a smaller surface area relative to the principal face(s), and/or the like. It should be understood that, when describing the semiconductor structure 104, the terms “surface” and “side” may be used interchangeably.

In some examples, such as that depicted in FIGS. 2-3, the semiconductor structure 104 may include a first major surface 104A-1 (e.g., front/top side/surface) (e.g., FIG. 2) and a second major surface 104A-2 (e.g., back/bottom/rear side/surface) (e.g., FIG. 3) (collectively, “sides 104A” and/or “surfaces 104A”). The second major surface 104A-2 may be generally opposite the first major surface 104A-1. The first major surface 104A-1 and the second major surface 104A-2 are hereinafter referred to as top surface 104A-1 and bottom surface 104A-2, respectively. As shown in FIGS. 2-3, the surfaces 104A may generally parallel relative to one another and may be the principal faces of the semiconductor structure 104 and/or the semiconductor die 108. As described herein, the semiconductor die 108 may include one or more metallization structures (e.g., contacts, electrodes, etc.) on the top surface 104A-1, the bottom surface 104A-2, and/or on both surfaces 104A.

The semiconductor structure 104 may further include one or more minor sides 104B adjacent to and extending between the surfaces 104A. More particularly, the semiconductor structure 104 may further include a first minor side 104B-1 (e.g., front/bottom side surface), a second minor side 104B-2 (e.g., top/back side surface), a third minor side 104B-3 (e.g., right side surface), and a fourth minor side 104B-4 (e.g., left side surface) (collectively, “sides 104B”). The first minor side 104B-1, the second minor side 104B-2, the third minor side 104B-3, and the fourth minor side 104B-4 are hereinafter referred to as side 104B-1, side 104B-2, side 104B-3, and side 104B-4, respectively. The side 104B-2 may be generally opposite the side 104B-1; the side 104B-4 may be generally opposite the side 104B-3. The sides 104B may be generally perpendicular to the surfaces 104A; the sides 104B-1, 104B-2 may be generally perpendicular to the sides 104B-3, 104B-4. The sides 104B-1, 104B-2 may be generally parallel relative to one another; the sides 104B-3, 104B-4 may be generally parallel relative to one another.

It should be understood that the semiconductor structure 104 and/or the semiconductor die 108 may include different arrangements of surfaces without deviating from the scope of the present disclosure.

The semiconductor die 108 may further include a protective layer 114, such as a passivation layer, that covers a substantial portion of the top surface 104A-1 (FIG. 2) of the semiconductor structure 104. The protective layer 114 may be formed from a dielectric material, such as, by way of non-limiting example, polyamide. Various bond pads and/or contacts may be exposed through openings 116 in the protective layer 114.

The semiconductor die 108 may further include one or more metallization structures (e.g., contacts, electrodes, etc.) on a major surface of the semiconductor structure 104, such as on the top surface 104A-1, the bottom surface 104A-2, and/or both surfaces 104A. For instance, in some examples (e.g., FIG. 2), the semiconductor die 108 may include one or more metallization structures (e.g., contacts, electrodes, etc.) on the top surface 104A-1 of the semiconductor structure 104.

For instance, in some examples (e.g., FIG. 2), the semiconductor die 108 may include a first metallization structure and a second metallization structure on the top surface 104A-1 of the semiconductor structure 104, such as a source metallization structure (e.g., source electrode 110) and a gate metallization structure (e.g., gate electrode 112), respectively. Additionally and/or alternatively, in some examples (e.g., FIG. 3), the semiconductor die 108 may further include a metallization structure on the bottom surface 104A-2 of the semiconductor structure 104, such as a drain metallization structure (e.g., drain electrode 118).

The metallization structure(s) (e.g., source electrodes 110, gate electrode 112, drain electrode 118) may include and/or be formed of a metal (e.g., aluminum) and/or a metal alloy (e.g., an aluminum-copper (AlCu) alloy). In some examples, each metallization structure (e.g., source electrodes 110, gate electrode 112, drain electrode 118) may include and/or be formed of the same material(s) (e.g., metal, metal alloy, etc.). In some examples, each metallization structure (e.g., source electrodes 110, gate electrode 112, drain electrode 118) may include and/or be formed of different material(s) (e.g., metal, metal alloy, etc.). Those having ordinary skill in the art, using the disclosures provided herein, will understand that the metallization structure(s) (e.g., source electrodes 110, gate electrode 112, drain electrode 118) may include and/or be formed of any suitable material without deviating from the scope of the present disclosure.

In some examples, the metallization structure(s) (e.g., source electrodes 110, gate electrode 112, drain electrode 118) may be a single-layered metallization structure having one layer (e.g., one metal layer, one metal alloy layer, etc.). Additionally and/or alternatively, in some examples, the metallization structure(s) (e.g., source electrodes 110, gate electrode 112, drain electrode 118) may be a multilayered metallization structure having a plurality of layers (e.g., a plurality of metal layers, a plurality of metal alloy layers, at least one metal layer and at least one metal alloy layer, etc.). In some examples, each metallization structure (e.g., source electrodes 110, gate electrode 112, drain electrode 118) may have the same number of layers. In other examples, each metallization structure (e.g., source electrodes 110, gate electrode 112, drain electrode 118) may have different numbers of layers. Those having ordinary skill in the art, using the disclosures provided herein, will understand that the metallization structure(s) (e.g., source electrodes 110, gate electrode 112, drain electrode 118) may include any suitable number of layers without deviating from the scope of the present disclosure.

The metallization structure(s) (e.g., source electrodes 110, gate electrode 112, drain electrode 118) may be coupled to terminals in a power semiconductor device package to provide a gate terminal, source terminal, and drain terminal (respectively) for the power semiconductor device 102 and/or the semiconductor die 108. In some examples, the metallization structure(s) (e.g., source electrodes 110, gate electrode 112, drain electrode 118) may be coupled to the respective terminals via wire bonds 120, which may be attached using any suitable technique (e.g., thermos-compression, soldering, etc.). For instance, in some examples (e.g., FIG. 2), the wire bonds 120 may be used to connect the source electrodes 110 and the gate electrode 112 to external voltage sources (not shown), such as terminals of other circuit elements.

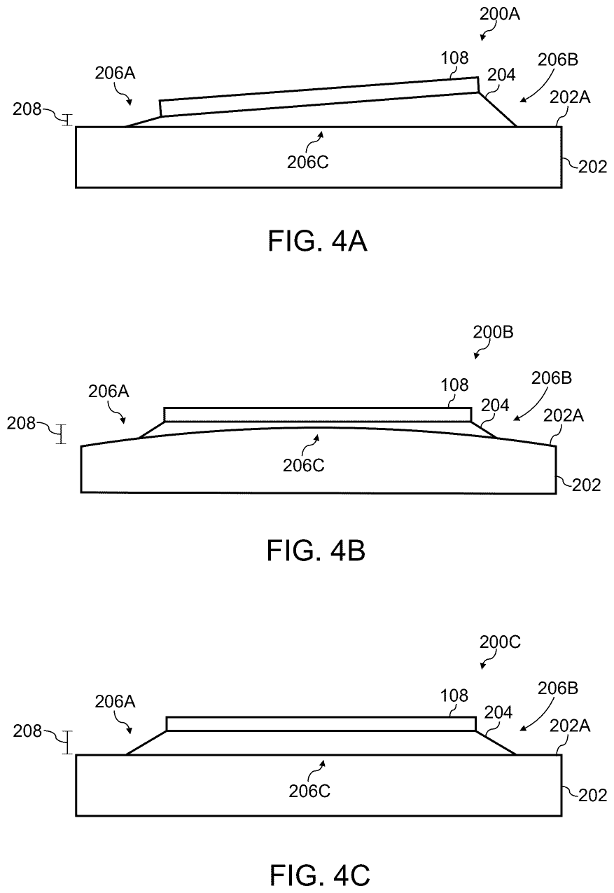

The semiconductor die 108 may be arranged in a power semiconductor device package, such as any of the power semiconductor device packages described herein. For instance, FIGS. 4A-4C depict cross-sectional views of an example power semiconductor device package 200 according to example embodiments of the present disclosure. More particularly, FIG. 4A depicts an example power semiconductor device package 200A, FIG. 4B depicts an example power semiconductor device package 200B, and FIG. 4C depicts an example power semiconductor device package 200C. It should be understood that the example power semiconductor device packages 200A, 200B, 200C may be collectively referred to herein as “power semiconductor device package 200” for purposes of illustration and discussion. It should be further understood that FIGS. 4A-4C are intended to represent structures for purposes of identification and description and are not intended to represent the structures to physical scale.

Referring generally to FIGS. 4A-4C, the power semiconductor device package 200 may include a semiconductor die, such as the semiconductor die 108. As shown, the semiconductor die 108 may be coupled to a submount 202. As will be discussed in greater detail below, the submount 202 may be any suitable supporting structure, such as a lead frame, a power substrate, and/or the like. The semiconductor die 108 may be coupled to the submount 202 with a die-attach material 204. The die-attach material 204 may be any suitable die-attach material, such as metal sintering die-attach, conductive adhesive die-attach, solder, paste, and/or the like. The semiconductor die 108 may be attached to the submount 202 using any suitable process, such as any of the process(es) described herein. For instance, the die-attach material 204 may be placed on a surface 202A of the submount 202, and the semiconductor die 108 (or other component) may be placed on the die-attach material 204, thereby defining an interface area 206 for the power semiconductor device package 200. The die-attach material 204 may be subjected to bonding and/or a bonding process (e.g., sintering) to secure the semiconductor die 108 (or other component) to the die-attach material 204 and, hence, to the submount 202.

As shown in FIGS. 4A-4C, a vertical height of the die-attach material 204 along a thickness direction T may define a bond-line thickness (BLT) 208 for the power semiconductor device package 200. More specifically, the BLT 208 may be measured from a top surface (e.g., surface 202A) of the submount 202 to a corresponding major surface (e.g., surface 104A) of the semiconductor die 108. Similarly, a uniformity of the BLT 208 across the interface area 206 between the submount 202 and the semiconductor die 108 may define a bond-line uniformity (BLU) 210 for the power semiconductor device package 200.

The thickness (e.g., BLT 208) and uniformity (e.g., BLU 210) of the die-attach material 204 may affect a number of operational characteristics of the power semiconductor device package 200. However, a variety of factors may pose difficulties and/or challenges for controlling the thickness (e.g., BLT 208) and uniformity (e.g., BLU 210) of the die-attach material 204 with respect to the semiconductor die 108 and the submount 202. For instance, nonplanarities in the surface 202A and/or the surface 104A, large attach areas (e.g., interface area 206), phase change(s) of the die-attach material 204 during the bonding process(es), and/or the like, may adversely affect the resulting BLT 208 and BLU 210.

As one illustrative example, FIG. 4A depicts the power semiconductor device package 200A having an inconsistent BLT 208 and, hence, a non-uniform BLU 210. More particularly, as shown, the BLT 208 at a first end 206A of the interface area 206 is thinner than the BLT 208 at a second end 206B of the interface area 206. As such, the power semiconductor device package 200A may have inconsistent electrical conductivity, thermal conductivity, and mechanical strength across the interface area 206. For instance, at the first end 206A, the (thinner) BLT 208 may result in higher electrical conductivity, higher thermal conductivity, and lower mechanical strength relative to the second end 206B; conversely, at the second end 206B, the (thicker) BLT 208 may result in lower electrical conductivity, lower thermal conductivity, and higher mechanical strength relative to the first end 206A.

As another illustrative example, FIG. 4B depicts the power semiconductor device package 200B having an inconsistent BLT 208 and, hence, a non-uniform BLU 210. In some instances, the non-uniform BLU 210 may be caused by thermomechanical stressors applied to the submount 202 during the packaging process, such as from pressure applied during reflow and/or curing of the die-attach material 204 and/or the like. More particularly, as shown, the BLT 208 at a center portion 206C of the interface area 206 may be thinner than the BLT 208 at the first end 206A and/or the second end 206B of the interface area 206. As such, like the power semiconductor device package 200A (FIG. 4A), the power semiconductor device package 200B may also have inconsistent electrical conductivity, thermal conductivity, and mechanical strength across the interface area 206. For instance, at the center portion 206C, the (thinner) BLT 208 may result in higher electrical conductivity, higher thermal conductivity, and lower mechanical strength relative to the first end 206A and the second end 206B.

As another illustrative example, FIG. 4C depicts the power semiconductor device package 200C having a consistent BLT 208 and, hence, a uniform BLU 210. More particularly, as shown, the BLT 208 may be consistent across the interface area 206. That is, the BLT 208 may be substantially uniform at the first end 206A and the second end 206B of the interface area 206, as well as in the center region 206C of the interface area 206. As such, in contrast to the power semiconductor device package 200A (FIG. 4A) and the power semiconductor device package 200B (FIG. 4B), the power semiconductor device package 200C may have consistent electrical conductivity, thermal conductivity, and mechanical strength across the interface area 206.

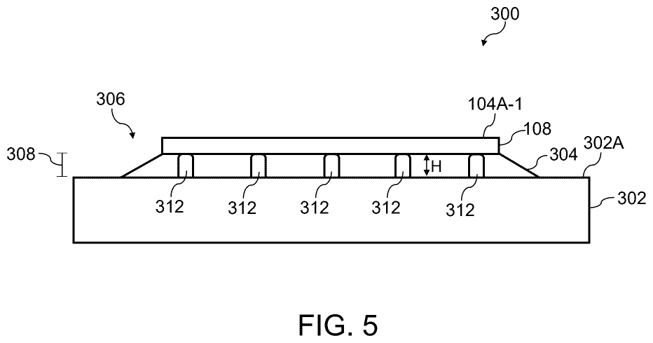

Accordingly, example aspects of the present disclosure are directed to power semiconductor device packages having integrated bond-line support structure(s) that are operable to provide optimized and consistent bond-line thickness and bond-line uniformity, such as that depicted above in FIG. 4C. For instance, FIG. 5 depicts a cross-sectional view of an example power semiconductor device package 300 according to example embodiments of the present disclosure. It should be understood that FIG. 5 is intended to represent structures for purposes of identification and description and is not intended to represent the structures to physical scale.

The power semiconductor device package 300 may be similar to any of the power semiconductor device packages described herein, such as the power semiconductor device package 200C (FIG. 4C) and/or the like. For instance, the power semiconductor device package 300 may include the semiconductor die 108. The semiconductor die 108 may be coupled to a submount 302, which may be similar to any of the submount(s) and/or supporting structure(s) described herein. As shown, the semiconductor die 108 may be coupled to the submount 302 via a die-attach material 304, which may be similar to any of the die-attach material(s) described herein. Additionally, the semiconductor die 108 may be coupled to the submount 302 using any suitable process, such as any of the process(es) described herein. For instance, the die-attach material 304 may be placed on a surface 302A of the submount 302, and the semiconductor die 108 may be placed on the die-attach material 304, thereby defining an interface area 306 for the power semiconductor device package 300. The die-attach material 304 may be subjected to bonding and/or a bonding process (e.g., sintering) to secure the semiconductor die 108 (or other component) to the die-attach material 304 and, hence, to the submount 302.

A vertical height of the die-attach material 304 along a thickness direction T may define a bond-line thickness (BLT) 308 for the power semiconductor device package 300. More specifically, as described above, the BLT 308 may be measured from a top surface (e.g., surface 302A) of the submount 302 to a corresponding major surface (e.g., surface 104A) of the semiconductor die 108. Similarly, a uniformity of the BLT 308 across the interface area 306 between the submount 302 and the semiconductor die 108 may define a bond-line uniformity (BLU) 310 for the power semiconductor device package 300.

To control the thickness (e.g., BLT 308) and uniformity (e.g., BLU 310) of the die-attach material 304, the power semiconductor device package 300 may further include one or more support structures 312 on one or more of the metallization structure(s) (e.g., source electrodes 110, gate electrode 112, drain electrode 118) of the semiconductor die 108. More particularly, as shown, the one or more support structures 312 may extend in a generally perpendicular direction away from a major surface 104A of the semiconductor structure 104. In some examples, the die-attach material 304 may at least partially contact the one or more support structures 312. As such, the power semiconductor device package 300 may have a BLT 308 that is substantially equal to a height H of the one or more support structures 312. Additionally, in some examples, the one or more support structures 312 may also counteract (and/or otherwise provide support against) packaging-related stressors applied to the submount 302, such as the thermomechanical stressors described above with reference to FIG. 4B. As such, the one or more support structures 312 may further provide for uniform BLU 310 of the die-attach material 304.

The one or more support structures 312 may include and/or otherwise be formed from any suitable material, such as any suitable conductive material or any suitable non-conductive material. For instance, in some examples, the one or more support structures 312 may include a metal, such as, by way of non-limiting example, copper (Cu), silver (Ag), gold (Au), titanium (Ti), platinum (Pt), palladium (Pd), nickel (Ni), aluminum (Al), and/or the like, and/or any suitable metal alloy thereof. In such examples, the metal (and/or metal alloy) of the one or more support structures 312 may be the same and/or different from a metal (and/or metal alloy) of the metallization structure(s) (e.g., source electrodes 110, gate electrode 112, drain electrode 118) of the semiconductor die 108. Additionally and/or alternatively, in some examples, the one or more support structures 312 may include a metal stack having a plurality of stacked metal layers (not shown). In such examples, each stacked metal layer may include a metal, such as, by way of non-limiting example, copper (Cu), silver (Ag), gold (Au), titanium (Ti), platinum (Pt), palladium (Pd), nickel (Ni), aluminum (Al), and/or the like, and/or any suitable metal alloy thereof.

The one or more support structures 312 may have a height H in a range of about 10 microns to about 250 microns, such as a height H in a range of about 15 microns to about 200 microns, such as a height H of about 100 microns. In some examples, the one or more support structures 312 may have a width W that is about 80 percent of the height H of the one or more support structures 312. In some examples, such as that depicted in FIG. 5, the one or more support structures 312 may have a uniform height H relative to one another. In some examples, the one or more support structures 312 may also have a uniform width W relative to one another, a uniform thickness T relative to one another, and/or the like. Additionally and/or alternatively, in other examples, a first support structure of the one or more support structures 312 may a first height H, and a second support structure of the one or more support structures 312 may have a second height H that is different from the first height H.

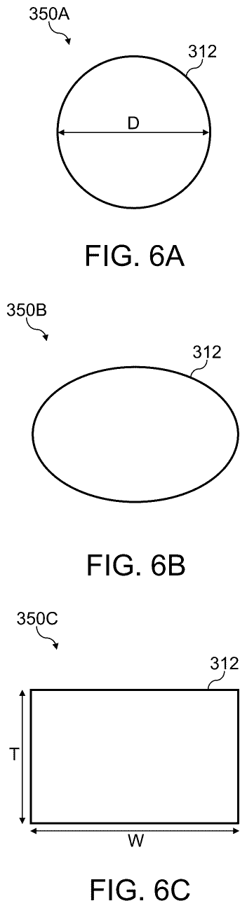

The one or more support structures 312 may have any suitable shape, cross-sectional shape, configuration, and/or the like. By way of non-limiting example, FIGS. 6A-6C depict cross-sectional plan views of the one or more support structures 312 according to example embodiments of the present disclosure. It should be understood that FIGS. 6A-6C are intended to represent structures for purposes of identification and description and are not intended to represent the structures to physical scale. As shown in FIG. 6A, in some examples, the one or more support structures 312 may, in some examples, have a circular cross-sectional shape 350A. In such examples, a diameter D of the one or more support structures 312 may be about 80 percent of the height H (FIG. 5) of the one or more support structures 312. Additionally and/or alternatively, as shown in FIG. 6B, the one or more support structures 312 may, in some examples, have an elliptical cross-sectional shape 350B. Additionally and/or alternatively, as shown in FIG. 6C, the one or more support structures 312 may, in some examples, have a rectangular cross-sectional shape 350C.

FIGS. 6A-6C depict example cross-sectional shapes of example support structures for purposes of illustration and discussion. Those having ordinary skill in the art, using the disclosures provided herein, will understand that different support structures having different cross-sectional shapes may be used without deviating from the scope of the present disclosure.

Referring again to the example depicted in FIG. 5, the one or more support structures 312 are depicted as pillars (e.g., having a cylindrical shape) on a backside metallization structure (e.g., drain electrode 118) of the power semiconductor device package 300 such that the one or more support structures 312 generally perpendicularly extend away from the (bottom) surface 104A-2 of the semiconductor structure 104. However, variations and modifications may be made to the power semiconductor device package 300 described herein without deviating from the scope of the present disclosure, such as a size, shape, configuration, arrangement, etc., of the supporting structure(s) (e.g., supporting structures 312, etc.) in the power semiconductor device package 300.

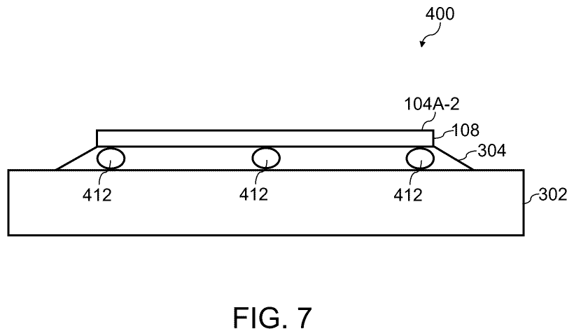

For instance, as a non-limiting illustrative example, FIG. 7 depicts a cross-sectional view of an example power semiconductor device package 400 according to example embodiments of the present disclosure. It should be understood that FIG. 7 is intended to represent structures for purposes of identification and description and is not intended to represent the structures to physical scale. The power semiconductor device package 400 may be similar to any of the power semiconductor device packages described herein, such as the power semiconductor device package 200C (FIG. 4C), the power semiconductor device package 300 (FIG. 5), and/or the like. For instance, the power semiconductor device package 400 may include the semiconductor die 108 coupled to the submount 302 via the die-attach material 304. However, in contrast to the power semiconductor device package 300 (FIG. 5), the power semiconductor device package 400 may include one or more support structures 412 on a topside metallization structure, such as the source electrodes 110, the gate electrode 112, and/or the like. As such, the one or more support structures 412 may extend in a generally perpendicular direction away from the (top) surface 104A-1 of the semiconductor structure 104. Additionally, in some examples, the one or more support structures 412 may have a different shape than the one or more support structures 312 (FIG. 5). More particularly, in the example depicted in FIG. 7, the one or more support structures 412 may be one or more balls having a spherical shape.

It should be understood that the one or more support structures 412 are depicted as having a spherical shape for purposes of illustration and discussion. Those having ordinary skill in the art, using the disclosures provided herein, will understand that the power semiconductor device package 400 may have any suitable support structure(s), such as the one or more support structures 312 (e.g., pillar(s) having a cylindrical shape), on the (top) surface 104A-1 of the semiconductor structure 104 without deviating from the scope of the present disclosure.

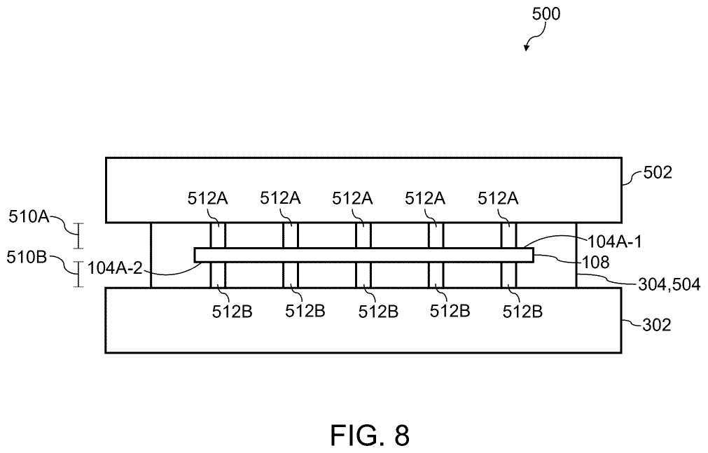

Additionally and/or alternatively, as another non-limiting illustrative example, FIG. 8 depicts a cross-sectional view of an example power semiconductor device package 500 according to example embodiments of the present disclosure. It should be understood that FIG. 8 is intended to represent structures for purposes of identification and description and is not intended to represent the structures to physical scale. The power semiconductor device package 500 may be similar to any of the power semiconductor device packages described herein, such as the power semiconductor device package 200C (FIG. 4C), the power semiconductor device package 300 (FIG. 5), the power semiconductor device package 400 (FIG. 7), and/or the like. For instance, the power semiconductor device package 500 may include the semiconductor die 108 coupled to the submount 302 via the die-attach material 304. However, the semiconductor die 108 may also be coupled to a submount 502, which may be similar to any of the submount(s) and/or supporting structure(s) described herein. In some examples, the submount 502 may be the same type of supporting structure relative the submount 302. In other examples, the submount 502 may be a different type of supporting structure relative to the submount 302. As shown, the semiconductor die 108 may be coupled to the submount via a die-attach material 504, which may be similar to any of the die-attach material(s) described herein. In some examples, the die-attach material 504 may be the same as the die-attach material 304. In other examples, the die-attach material 504 may be different from the die-attach material 304.

The power semiconductor device package 500 may further include one or more first support structures 512A on a first metallization structure (e.g., source electrodes 110, gate electrode 112, etc.) and one or more second support structures 512B on a second metallization structure (e.g., drain electrode 118, etc.). In some examples, the one or more first support structures 512A and the one or more second support structures 512B may generally perpendicularly extend in opposite directions relative to the semiconductor structure 104. Put differently, as shown, the one or more first support structures 512A may extend in a generally perpendicular direction away from the (top) surface 104A-1 of the semiconductor structure 104, and the one or more second support structures 512B may extend in a generally perpendicular direction away from the (bottom) surface 104A-2 of the semiconductor structure 104. In this way, the one or more first support structures 512A may control the thickness (e.g., BLT 508A) and uniformity (e.g., BLU 510A) of the die-attach material 504 (e.g., between the semiconductor die 108 and the submount 502), and the one or more second support structures 512B may control the thickness (e.g., BLT 508B) and uniformity (e.g., BLU 510B) of the die-attach material 304 (e.g., between the semiconductor die 108 and the submount 302).

In some examples, the one or more first support structures 512A may be similar to and/or the same as the one or more second support structures 512B. For instance, in some examples, the one or more first support structures 512A and the one or more second support structures 512B may include and/or otherwise be formed from the same material (e.g., conductive material, non-conductive material, metal, metal alloy, etc.). Additionally and/or alternatively, in some examples, the one or more first support structures 512A may have a first shape (e.g., cylindrical shape, spherical shape, etc.), and the one or more second support structures 512B may have a second shape (e.g., cylindrical shape, spherical shape, etc.) that is the same as the first shape. Additionally and/or alternatively, in some examples, the one or more first support structures 512A may have a first cross-sectional shape (e.g., circular cross-sectional shape, elliptical cross-sectional shape, rectangular cross-sectional shape, etc.), and the one or more second support structures 512B may have a second cross-sectional shape (e.g., circular cross-sectional shape, elliptical cross-sectional shape, rectangular cross-sectional shape, etc.) that is the same as the first cross-sectional shape. Additionally and/or alternatively, in some examples, the one or more first support structures 512A may be arranged in a first pattern on the first metallization structure (e.g., source electrodes 110, gate electrode 112, etc.), and one or more second support structures 512B may be arranged in a second pattern on a second metallization structure (e.g., drain electrode 118, etc.) that is the same as the first pattern.

In other examples, the one or more first support structures 512A may be different from the one or more second support structures 512B. For instance, in some examples, the one or more first support structures 512A may include and/or otherwise be formed from a first material (e.g., first conductive material, first non-conductive material, first metal, first metal alloy, etc.), and the one or more second support structures 512B may include and/or otherwise be formed from a second material (e.g., second conductive material, second non-conductive material, second metal, second metal alloy, etc.) that is different from the first material. Additionally and/or alternatively, in some examples, the one or more first support structures 512A may have a first shape (e.g., cylindrical shape, spherical shape, etc.), and the one or more second support structures 512B may have a second shape (e.g., cylindrical shape, spherical shape, etc.) that is different from the first shape. Additionally and/or alternatively, in some examples, the one or more first support structures 512A may have a first cross-sectional shape (e.g., circular cross-sectional shape, elliptical cross-sectional shape, rectangular cross-sectional shape, etc.), and the one or more second support structures 512B may have a second cross-sectional shape (e.g., circular cross-sectional shape, elliptical cross-sectional shape, rectangular cross-sectional shape, etc.) that is different from the first cross-sectional shape. Additionally and/or alternatively, in some examples, the one or more first support structures 512A may be arranged in a first pattern on the first metallization structure (e.g., source electrodes 110, gate electrode 112, etc.), and one or more second support structures 512B may be arranged in a second pattern on a second metallization structure (e.g., drain electrode 118, etc.) that is different from the first pattern.

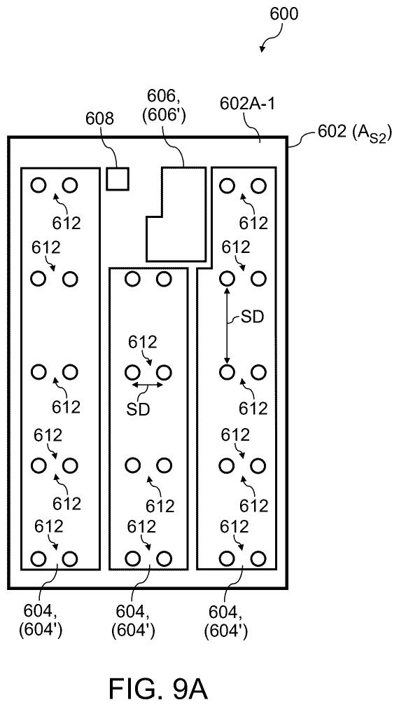

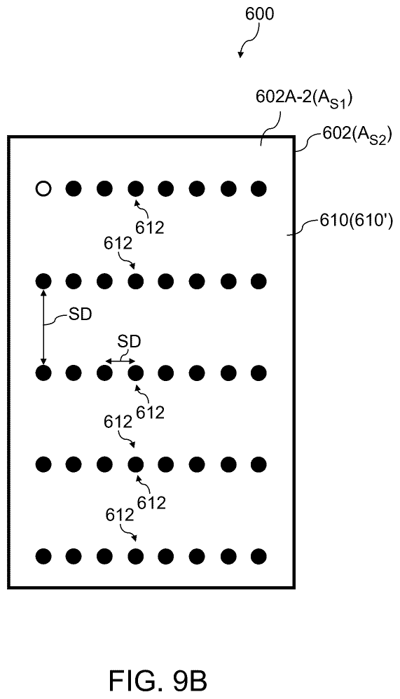

Additional variations and modifications may be made to the example power semiconductor device packages described herein (e.g., power semiconductor device package 300, 400, 500) without deviating from the scope of the present disclosure, such as a size, shape, configuration, arrangement, etc., of the supporting structure(s) on the semiconductor die 108. As a non-limiting illustrative example, FIGS. 9A-9B depict plan views of an example semiconductor die 600 according to example embodiments of the present disclosure. More particularly, FIG. 9A depicts a top plan view of the example semiconductor die 600, and FIG. 9B depicts a bottom plan view of the example semiconductor die 600. It should be understood that FIGS. 9A-9B are intended to represent structures for purposes of identification and description and are not intended to represent the structures to physical scale.

The semiconductor die 600 may be similar to any of the semiconductor die described herein, such as the semiconductor die 108 (FIGS. 1-8) and/or the like. For instance, the semiconductor die 600 may include a semiconductor structure 602, which may be similar to the semiconductor structure 104 (FIGS. 1-8) and/or the like. The semiconductor die 600 may also include one or more metallization structure(s) (e.g., contacts, electrodes, etc.) on a major surface 602A of the semiconductor structure 602, such as on a top surface 602A-1 (FIG. 9A), a bottom surface 602A-2 (FIG. 9B), and/or both major surfaces 602A (FIGS. 9A-9B). However, in contrast to the semiconductor die 108 (FIGS. 1-8), the metallization structure(s) (e.g., contacts, electrodes, etc.) may have a different arrangement on the corresponding major surface 602A of the semiconductor die 600.

For instance, as shown in FIG. 9A, the semiconductor die 600 may include one or more source metallization structures 604 (e.g., defining a source metallization footprint 604′) and one or more gate metallization structures 606 (e.g., defining a gate metallization footprint 606′) on the top surface 602A-1. In some examples, such as that depicted in FIG. 9A, the semiconductor die 600 may further include an additional metallization structure 608 (e.g., source-kelvin metallization structure, sensor metallization structure, etc.) on the top surface 602A-1. Similarly, as shown in FIG. 9B, the semiconductor die 600 may include a drain metallization structure 610 (e.g., defining a drain metallization footprint 610′) on the bottom surface 602A-2.

The semiconductor die 600 may further include a plurality of support structures 612 on a topside metallization structure (e.g., source metallization structure(s) 604, gate metallization structure(s) 606, additional metallization structure 608, etc.), a backside metallization structure (e.g., drain metallization structure 610, etc.), and/or on both a topside metallization structure and a backside metallization structure. Each of the plurality of support structures 612 may be similar to any of the support structure(s) described herein.

In some examples (e.g., FIG. 9A), one or more of the plurality of support structures 612 may be on the top surface 602A-1 of the semiconductor die 600. In such examples, the support structure(s) 612 may be arranged within the source metallization footprint 604′ defined by the source metallization structure 604. That is, the support structure(s) 612 may be spaced apart from the gate metallization footprint 606′ defined by the gate metallization structure 606. Additionally and/or alternatively, in some examples (e.g., FIG. 9B), one or more the plurality of support structures 612 may be on the bottom surface 602A-2 of the semiconductor die 600. In such examples, the support structure(s) 612 may be arranged within the drain metallization footprint 610′ defined by the drain metallization structure 610.

It should be understood that the support structure(s) 612 are depicted in FIG. 9A as being arranged within the source metallization footprint 604′ (e.g., defined by the source metallization structure 604) and spaced apart from the gate metallization footprint 606′ (e.g., defined by the gate metallization structure 606) for purposes of illustration and discussion. Those having ordinary skill in the art, using the disclosures provided herein, will understand that the support structure(s) 612 may be arranged on the gate metallization structure 606 and/or within the gate metallization footprint 606′ without deviating from the scope of the present disclosure.

In some examples, the plurality of support structures 612 may be arranged in an array on the corresponding metallization structure, such as in an array on one or more of the source metallization structures 604 (FIG. 9A), in an array on the drain metallization structure 610 (FIG. 9B), and/or in an array on both the drain metallization structure 610 and one or more of the source metallization structures 604. More particularly, each support structure 612 may be spaced apart from one another by a separation distance SD, which may be in a range of about 5 percent to about 20 percent of a surface area As of the corresponding major surface (e.g., surface 602A-1, surface 602A-2). For instance, as shown in FIG. 9A, each support structure 612 may have a separation distance SD that is in a range of about 5 percent to about 20 percent of a surface area A_{S1} of the top surface 602A-1. Similarly, as shown in FIG. 9B, each support structure 612 may have a separation distance SD that is in a range of about 5 percent to about 20 percent of a surface area A_{S1} of the bottom surface 602A-2. In this way, a planar density of the plurality of support structures 612 on the corresponding major surface (e.g., surface 602A-1, surface 602A-2) may be in a range of about 5 percent to about 20 percent of a surface area A_{S2} of the semiconductor structure 602.

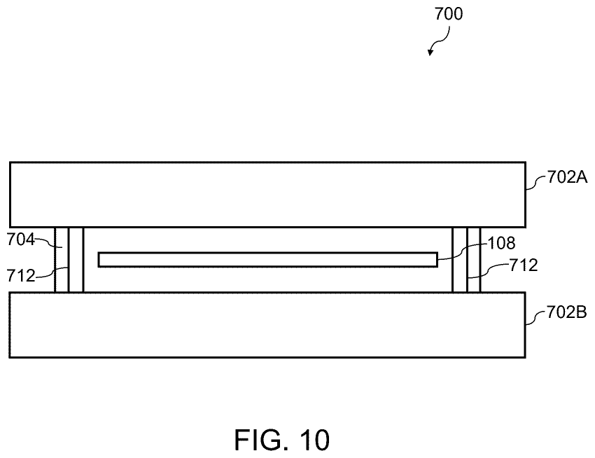

Additional variations and modifications may be made to the example power semiconductor device packages described herein (e.g., power semiconductor device package 300, 400, 500) without deviating from the scope of the present disclosure, such as a size, shape, configuration, arrangement, etc., of the supporting structure(s) within the power semiconductor device package. As a non-limiting illustrative example, FIG. 10 depicts a cross-sectional view of an example power semiconductor device package 700 according to example embodiments of the present disclosure. The power semiconductor device package 700 may be similar to any of the power semiconductor device packages described herein, such as the power semiconductor device package 200C (FIG. 4C), the power semiconductor device package 300 (FIG. 5), the power semiconductor device package 400 (FIG. 7), the power semiconductor device package 400 (FIG. 7), the power semiconductor device package 500 (FIG. 8), and/or the like. For instance, the power semiconductor device package 700 may include the semiconductor die 108 coupled to a first submount 702A and to a second submount 702B via a die-attach material 704. The submounts 702A, 702B and the die-attach material 704 may be similar to any of the submounts and die-attach materials described herein (respectively). The power semiconductor device package 700 may further include one or more support structures 712, which may be similar to any of the support structures described herein. However, in the example power semiconductor device package 700, the support structures 712 extend in a generally perpendicular direction between the first submount 702A and the second submount 702B, thereby controlling a thickness (e.g., BLT) and uniformity (e.g., BLU) of the die-attach material 704 (e.g., between the first submount 702A and the second submount 702B).

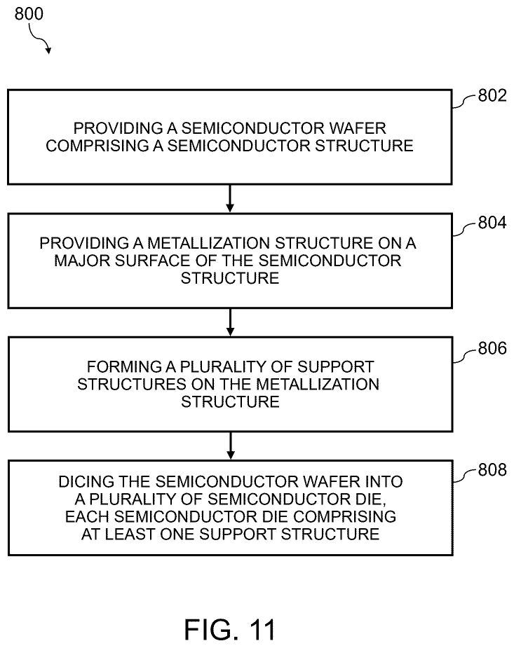

FIG. 11 depicts a flow chart diagram of an example method 800 according to example embodiments of the present disclosure. FIG. 11 depicts example process steps for purposes of illustration and discussion. Those having ordinary skill in the art, using the disclosures provided herein, will understand that the process steps of any of the methods described in the present disclosure may be adapted, modified, include steps not illustrated, omitted, and/or rearranged without deviating from the scope of the present disclosure.

At 802, the method 800 includes providing a semiconductor wafer. The semiconductor wafer may include a semiconductor structure.

At 804, the method 800 includes providing a metallization structure on a major surface of the semiconductor structure. In some examples, a first metallization structure and a second metallization structure may be provided on the major surface of the semiconductor structure. More particularly, in some examples, the metallization structure may be a drain metallization structure (e.g., drain electrode) on a bottom surface of the semiconductor structure. Additionally and/or alternatively, in some examples, the metallization structure may be one or more source metallization structure(s) (e.g., source electrode(s)) on a top surface of the semiconductor structure. Additionally and/or alternatively, in some examples, the metallization structure may be one or more gate metallization structure(s) (e.g., gate electrode(s)) on a top surface of the semiconductor structure.

At 806, the method 800 includes forming a plurality support structures on the metallization structure. In some examples, the plurality of support structures may be formed on a source metallization structure on a top surface of the semiconductor structure. In some examples, the plurality of support structures may be formed on a drain metallization structure on a bottom surface of the semiconductor structure.

At 808, the method 800 includes dicing the semiconductor wafer into a plurality of semiconductor die. Each semiconductor die may include at least one support structure.

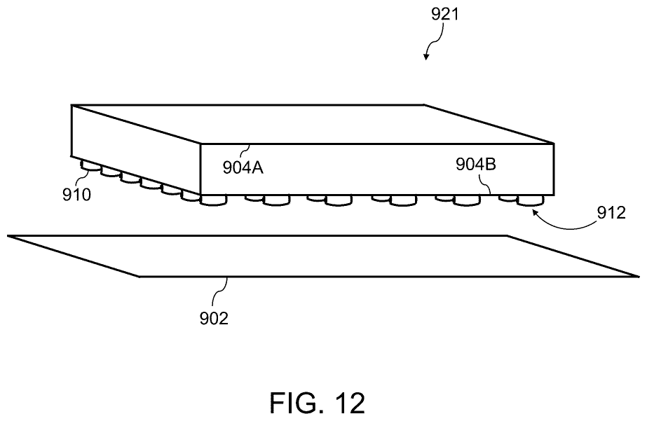

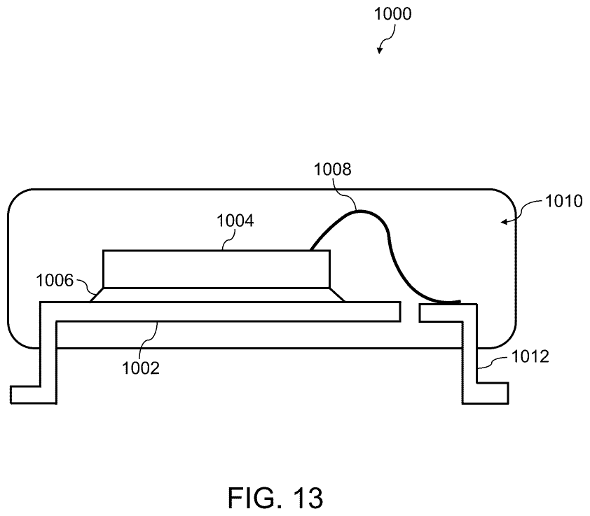

FIG. 12 depicts an exploded, perspective view of an example stud protrusion 921 configuration on an example semiconductor die 904. In some embodiments, the semiconductor die 904 may include at least one stud protrusion 910 extending from the semiconductor die 904 toward the submount 902. The at least one stud protrusion 910 may be similar to any of the support structures described herein. More particularly, as shown, the at least one stud protrusion 910 may extend from a bottom surface 904B of the semiconductor die 904 toward the submount 902. In some embodiments, the at least one stud protrusion 910 may be prefabricated and attached to the bottom surface 904B of the semiconductor die 904. Furthermore, as noted above, the stud protrusion(s) 910 may have a height in a range of about 1 micron to about 20 microns, such as about 2 microns to about 15 microns, such as about 3 microns to about 10 microns.

The at least one stud protrusion 910 may include a planar surface 912. In some embodiments, the submount 902 may be arranged on the planar surface 912 of the at least one stud protrusion 910. In this manner, the submount 902 may directly contact the planar surface 912 of the at least one stud protrusion 910. A surface area of the planar surface 912 may be less than about ten percent (10%) of a surface area of the submount 902. Furthermore, in some embodiments, the surface area of the planar surface 912 may be less than about five percent (5%) of a surface area of the submount 902.

Furthermore, it should be noted that, although not depicted in FIG. 12, the stud protrusions 910 may be configured on the bottom surface 904B of the semiconductor die 904. That is, the stud protrusions 910 may have a square cross-section, a circular cross-section, and/or any suitable shape cross-section. Additionally, the semiconductor die 904 may include at least one stud protrusion 910 in a center portion of the bottom surface 904B of the semiconductor die 904 and/or at least one stud protrusion 910 in a peripheral portion of the bottom surface 904B of the semiconductor die 904

In some embodiments, the semiconductor die 904 may include a plurality of stud protrusions 910 arranged in an array on the bottom surface 904B of the semiconductor die 904. In such embodiments, as will be discussed in greater detail below, die-attach material and/or electroless deposited material may be disposed between at least a portion of the semiconductor die 904 and the submount 902. More particularly, the die-attach material and/or electroless deposited material may partially fill a space between adjacent stud protrusions 810 on the bottom surface 904B of the semiconductor die 904.

It should be appreciated that semiconductor die according to example aspects of the present disclosure may have any number of stud protrusions without deviating from the scope of the present disclosure. The number and configuration of stud protrusions in FIG. 12 are provided for purposes of illustration and discussion.

FIG. 13 depicts an example power semiconductor device package 1000 of a power semiconductor device according to example embodiments of the present disclosure. The power semiconductor device package 1000 may be, for instance, a discrete power semiconductor device package. FIG. 13 is provided for purposes of illustration and discussion. Those having ordinary skill in the art, using the disclosures provided herein, will understand that aspects of the present disclosure may be used in a variety of devices and/or applications without deviating from the scope of the present disclosure. Furthermore, FIG. 13 is intended to represent structures for identification and description and is not intended to represent the structures to physical scale.

As shown, the power semiconductor device package 1000 may include a conductive submount 1002 (e.g., a patterned conductive substrate, lead frame, clip structure or other power substrate) on which a semiconductor die 1004 containing one or more power devices (e.g., transistors, diodes, etc.) is attached using a die-attach material 1006. It should be understood that the semiconductor die 1004 may correspond to any of the semiconductor die disclosed herein (e.g., semiconductor die 108, semiconductor die 600, semiconductor die 804, etc.) and may be fabricated using any of the methods disclosed herein.

The die-attach material 1006 may provide a thermal, mechanical, and electrical connection between the semiconductor die 1004 and the conductive submount 1002. In some examples, the semiconductor die 1004 may also be connected to the conductive submount 1002 using wire bonds 1008. An encapsulating material 1010 (e.g., epoxy mold compound (EMC), ceramic-based encapsulating material, silicon-based encapsulating material, polymer-based encapsulating material, etc.) may fill the space around the semiconductor die 1004 and the submount 1002, thereby forming a housing. The power semiconductor device package 1000 may further include one or more connection structures, such as electrical leads 1012, that extend outward from the housing (e.g., outward from the encapsulating material 1010).

The power semiconductor device package 1000 may include one or more metallization structures, such as any of the metallization structures disclosed herein. More particularly, the semiconductor die 1004 may include one or more metallization structures, such as bonding pads. The power semiconductor device package 1000 may further include one or more support structures (not shown), such as any of the support structure(s) described herein, on a major surface of the one or more metallization structures. The bonding pads may be coupled to the one or more electrical leads 1012 using the wire bonds 1008. The wire bonds 1008 may be aluminum and/or copper. The wire bonds 1008 may have a thickness of about 15 mil to about 20 mil (e.g., about 381 μm to about 508 μm). As noted above, the bonding pads may have a thickness, for instance, of about 4 μm or less. A backside metallization layer on the semiconductor die 1004 may be coupled to the submount 1002 (e.g., lead frame) using, for instance, the die-attach material 1006. The encapsulating material 1010 may encapsulate the semiconductor die 1004, including its metallization structures, wire bonds 1008, submount 1002, and other portions of the power semiconductor device package 1000. In some examples, the encapsulating material 1010 may directly contact the metallization structures (e.g., bonding pads, backside metallization layer, etc.) of the power semiconductor device package 1000.

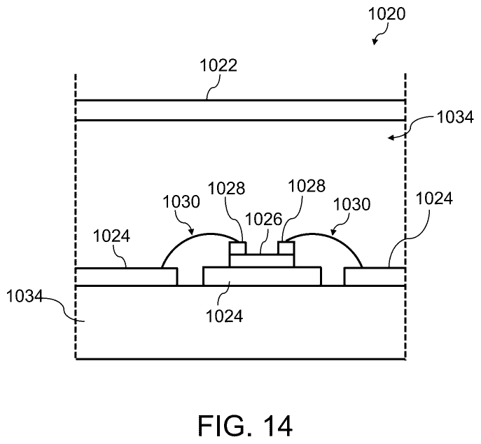

FIG. 14 depicts a cross-sectional view of an example power semiconductor device package of a semiconductor device 1020 according to example embodiments of the present disclosure. The semiconductor device 1020 of FIG. 14 is a portion of a power module. FIG. 14 is intended to represent structures for identification and description and is not intended to represent the structures to physical scale. The semiconductor device 1020 may include a housing 1022. The semiconductor device 1020 may include a conductive submount 1024 (e.g., a patterned conductive submount) on which a semiconductor die 1026 is mounted (e.g., using a die-attach material). It should be understood that the semiconductor die 1026 may correspond to any of the semiconductor die disclosed herein (e.g., semiconductor die 108, semiconductor die 600, semiconductor die 804, etc.) and may be fabricated using any of the methods disclosed herein. For instance, the semiconductor die 1026 may be mounted on submount 1024 using a die-attach material that includes a sintered material, such as sintered silver and/or sintered copper. The submount 1024 may be similar to any of the submounts described herein. The semiconductor die 1026 may include one or more metallization structures, such as bonding pads 1028. The semiconductor die 1026 may further include one or more support structures (not shown), such as any of the support structure(s) described herein, on a major surface of the one or more metallization structures. In some examples, the semiconductor die 1026 may be connected to the conductive submount 1024 using wire bonds 1030. The conductive submount 1024 may be mounted on a base layer 1032 (e.g., an insulating layer). An inert gel 1034 may fill the space between the semiconductor die 1026 and the housing 1022.

FIGS. 13-14 depict example semiconductor packages for purposes of illustration and discussion. Those of ordinary skill in the art, using the disclosures provided herein, will understand that different semiconductor package configurations may be used without deviating from the scope of the present disclosure.

Example aspects of the present disclosure are set forth below. Any of the below features or examples may be used in combination with any of the embodiments or features provided in the present disclosure.

One example aspect of the present disclosure is directed to a semiconductor die. The semiconductor die includes a semiconductor structure, a metallization structure on a major surface of the semiconductor structure, and one or more support structures on the metallization structure.

In some examples, the one or more support structures extend in a generally perpendicular direction away from the major surface of the semiconductor structure.

In some examples, the metallization structure is on a bottom surface of the semiconductor structure.

In some examples, the metallization structure is a drain electrode on the bottom surface of the semiconductor structure.

In some examples, the semiconductor die includes at least three support structures on the metallization structure.

In some examples, the metallization structure is on a top surface of the semiconductor structure.

In some examples, the metallization structure is a first metallization structure, and the semiconductor die further includes a second metallization structure on the top surface of the semiconductor structure. In some examples, the first metallization structure is a source metallization structure, the source metallization structure defining a source metallization footprint on the top surface of the semiconductor structure. In some examples, the second metallization structure is a gate metallization structure, the gate metallization structure defining a gate metallization footprint on the top surface of the semiconductor structure.

In some examples, the one or more support structures are arranged within the source metallization footprint.

In some examples, the one or more support structures are spaced apart from the gate metallization footprint.

In some examples, the one or more support structures are a plurality of support structures on the metallization structure.

In some examples, each of the plurality of support structures have a uniform height relative to one another.

In some examples, each of the plurality of support structures have a uniform thickness relative to one another.

In some examples, each of the plurality of support structures have a uniform width relative to one another.

In some examples, the plurality of support structures are arranged in an array on the metallization structure.

In some examples, each support structure is spaced apart from other support structures of the plurality of support structures by a separation distance, and the separation distance is about five percent of a surface area of the major surface of the semiconductor structure.

In some examples, a planar density of the plurality of support structures on the metallization structure is in a range of about 5 percent to about 20 percent of a surface area of the major surface of the semiconductor structure.

In some examples, the one or more support structures include a non-conductive material.

In some examples, the one or more support structures include a conductive material.

In some examples, the one or more support structures include a metal.

In some examples, the metal of the one or more support structures is different from a metal of the metallization structure.

In some examples, the metal is one of copper (Cu), silver (Ag), gold (Au), titanium (Ti), platinum (Pt), palladium (Pd), nickel (Ni), or aluminum (Al).

In some examples, the metal is a metal alloy.

In some examples, the metal is a metal stack comprising a plurality of stacked metal layers.

In some examples, the one or more support structures include a first support structure having a first height and a second support structure having a second height that is different from the first height.

In some examples, the metallization structure is a first metallization structure, and the semiconductor die further includes a second metallization structure on the major surface of the semiconductor structure. In some examples, the first support structure is on the first metallization structure and the second support structure is on the second metallization structure.

In some examples, the first metallization structure is a source metallization structure, and the second metallization structure is a gate metallization structure.

In some examples, a height of the one or more support structures is in a range of about 10 microns to about 250 microns.

In some examples, the height of the one or more support structures is in a range of about 15 microns to about 200 microns.

In some examples, the height of the one or more support structures is about 100 microns.

In some examples, a diameter of the one or more support structures is about 80 percent of a height of the one or more support structures.

In some examples, the one or more support structures are a different material relative to the metallization structure.

In some examples, the one or more support structures the same material relative to the metallization structure.

In some examples, the one or more support structures include one or more metal pillars having a cylindrical shape.

In some examples, the one or more support structures include one or more metal balls having a spherical shape.

In some examples, the one or more support structures have a circular cross-sectional shape.

In some examples, the one or more support structures have an elliptical cross-sectional shape.

In some examples, the one or more support structures have a rectangular cross-sectional shape.

In some examples, the metallization structure is a first metallization structure on a top surface of the semiconductor structure, and the semiconductor die further includes a second metallization structure on a bottom surface of the semiconductor structure. In some examples, the one or more support structures include one or more first support structures on the first metallization structure and one or more second support structures on the second metallization structure.

In some examples, the one or more first support structures are formed from a first material, and the one or more second support structures are formed from a second material that is different from the first material.

In some examples, the one or more first support structures and the one or more second support structures are formed from the same material.

In some examples, the one or more first support structures have a first shape, and the one or more second support structures have a second shape that is different from the first shape.

In some examples, the one or more first support structures have a first shape, and the one or more second support structures have a second shape that is the same as the first shape.

In some examples, the one or more first support structures have a first cross-sectional shape, and the one or more second support structures have a second cross-sectional shape that is different from the first cross-sectional shape.

In some examples, the one or more first support structures have a first cross-sectional shape, and the one or more second support structures have a second cross-sectional shape that is the same as the first cross-sectional shape.

In some examples, the one or more first support structures are arranged in a first pattern on the first metallization structure, and the one or more second support structures are arranged in a second pattern on the second metallization structure that is different from the first pattern.

In some examples, the one or more first support structures are arranged in a first pattern on the first metallization structure, and the one or more second support structures are arranged in a second pattern on the second metallization structure that is the same as the first pattern.

In some examples, the one or more first support structures and the one or more second support structures generally perpendicularly extend in opposite directions relative to the semiconductor structure.

In some examples, the metallization structure is a multilayered metallization structure.

In some examples, the semiconductor structure includes a wide bandgap semiconductor material.

In some examples, the wide bandgap semiconductor material is one of silicon carbide (SiC) or a Group III-nitride.

In some examples, the semiconductor die is arranged in a power semiconductor device package.

In some examples, the power semiconductor device package has a bond-line thickness (BLT) that is substantially equal to a height of the one or more support structures.

In some examples, the power semiconductor device package is one of a discrete power semiconductor device package or a power module.

In some examples, the semiconductor die is coupled to a submount in the power semiconductor device package with a die-attach material, the die-attach material at least partially contacting the one or more support structures.

In some examples, the semiconductor die is coupled to the submount at an interface area, and the power semiconductor device package has a bond-line uniformity (BLU) that is substantially uniform across the interface area.

In some examples, the submount is a lead frame.

In some examples, the submount is a power substrate. In some examples, the power substrate includes a plurality of metal layers and an insulating layer between the metal layers.

In some examples, the power substrate is one of a direct bonded copper (DBC) substrate or an active metal brazed (AMB) substrate.

In some examples, the power semiconductor device package includes a housing formed from an encapsulating material. In some examples, the encapsulating material includes one of an epoxy mold compound (EMC), a ceramic-based encapsulating material, a silicon-based encapsulating material, or a polymer-based encapsulating material.

In some examples, the semiconductor die is one of a metal-oxide-semiconductor field-effect transistor (MOSFET), a Schottky diode, or an insulated gate bipolar transistor (IGBT).

Another example aspect of the present disclosure is directed to a power semiconductor device package. The power semiconductor device package includes a submount. The power semiconductor device package further includes a semiconductor die. The semiconductor die includes a semiconductor structure, a metallization structure on a major surface of the semiconductor structure, and one or more support structures on the metallization structure. The power semiconductor device package further includes a die-attach material around the one or more support structures between the semiconductor die and the submount, the die-attach material coupling the semiconductor die to the submount.

Another example aspect of the present disclosure is directed to a method. The method includes providing a semiconductor wafer comprising a semiconductor structure. The method further includes providing a metallization structure on a major surface of the semiconductor structure. The method further includes forming a plurality of support structures on the metallization structure. The method further includes dicing the semiconductor wafer into a plurality of semiconductor die, each semiconductor die comprising at least one support structure.

In some examples, the metallization structure is on a bottom surface of the semiconductor structure.

In some examples, the metallization structure is a drain electrode on the bottom surface of the semiconductor structure.

In some examples, the plurality of support structures include at least three support structures.

In some examples, the metallization structure is on a top surface of the semiconductor structure.

In some examples, the metallization structure is a source electrode on the top surface of the semiconductor structure.

In some examples, providing the metallization structure on the major surface of the semiconductor structure includes providing a source metallization structure on a top surface of the semiconductor structure and providing a gate metallization structure on the top surface of the semiconductor structure.

In some examples, the plurality of support structures are formed on the source metallization structure.

In some examples, providing the metallization structure on the major surface of the semiconductor structure includes providing a first metallization structure on a top surface of the semiconductor structure and providing a second metallization structure on a bottom surface of the semiconductor structure.

In some examples, forming a plurality of support structures on the metallization structure includes forming a plurality of first support structures on the first metallization structure and forming a plurality of second support structures on the second metallization structure.

Another example aspect of the present disclosure is directed to a power semiconductor device package. The power semiconductor device package includes a submount. The power semiconductor device package further includes a semiconductor die on the submount. The semiconductor die includes a semiconductor structure, a metallization structure on a bottom surface of the semiconductor structure, and a plurality of support structures on the metallization structure. The power semiconductor device package further includes a die-attach material coupling the semiconductor die to the submount. The power semiconductor device package further includes a housing comprising an encapsulating material formed around at least a portion of the submount and the semiconductor die.

Another example aspect of the present disclosure is directed to a semiconductor die. The semiconductor die includes a semiconductor structure, a source metallization structure on a top surface of the semiconductor structure, a drain metallization structure on a bottom surface of the semiconductor structure, one or more first support structures on the source metallization structure, and one or more second support structures on the drain metallization structure.

Another example aspect of the present disclosure is directed to a power semiconductor device package. The power semiconductor device package includes a first submount, a second submount, and one or more support structures contacting the first submount and the second submount such that the one or more support structures are between the first submount and the second submount.

In some examples, the first submount is a power substrate.

In some examples, the second submount is a power substrate.

In some examples, a semiconductor die is on at least one of the first submount or the second submount.

In some examples, the power semiconductor device package includes a housing formed from an encapsulating material.

In some examples, the encapsulating material includes one of an epoxy mold compound (EMC), a ceramic-based encapsulating material, a silicon-based encapsulating material, or a polymer-based encapsulating material.

While the present subject matter has been described in detail with respect to specific example embodiments thereof, it will be appreciated that those skilled in the art, upon attaining an understanding of the foregoing can readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A semiconductor die, comprising:
a semiconductor structure;
a metallization structure on a major surface of the semiconductor structure; and
one or more support structures on the metallization structure.

2. The semiconductor die of claim 1, wherein the one or more support structures extend in a generally perpendicular direction away from the major surface of the semiconductor structure.

3. The semiconductor die of claim 1, wherein the metallization structure is on a bottom surface of the semiconductor structure.

4. The semiconductor die of claim 1, wherein the metallization structure is on a top surface of the semiconductor structure.

5. The semiconductor die of claim 1, wherein the one or more support structures are a plurality of support structures on the metallization structure.

6. The semiconductor die of claim 5, wherein each of the plurality of support structures have a uniform height relative to one another.

7. The semiconductor die of claim 5, wherein the plurality of support structures are arranged in an array on the metallization structure, and wherein each support structure is spaced apart from other support structures of the plurality of support structures by a separation distance, and wherein the separation distance is about five percent of a surface area of the major surface of the semiconductor structure.

8. The semiconductor die of claim 5, wherein a planar density of the plurality of support structures on the metallization structure is in a range of about 5 percent to about 20 percent of a surface area of the major surface of the semiconductor structure.

9. The semiconductor die of claim 1, wherein the one or more support structures comprise a metal, and wherein the metal is one of:
copper (Cu);
silver (Ag);
gold (Au);
titanium (Ti);
platinum (Pt);
palladium (Pd);
nickel (Ni); or
aluminum (Al).

10. The semiconductor die of claim 1, wherein the one or more support structures comprise:
a first support structure having a first height; and
a second support structure having a second height that is different from the first height.

11. The semiconductor die of claim 10, wherein the metallization structure is a first metallization structure, the semiconductor die further comprising:
a second metallization structure on the major surface of the semiconductor structure,
wherein the first support structure is on the first metallization structure and the second support structure is on the second metallization structure.

12. The semiconductor die of claim 1, wherein a height of the one or more support structures is in a range of about 10 microns to about 250 microns.

13. The semiconductor die of claim 1, wherein the one or more support structures comprise one or more metal pillars having a cylindrical shape or one or more metal balls having a spherical shape.

14. The semiconductor die of claim 1, wherein the metallization structure is a first metallization structure on a top surface of the semiconductor structure, the semiconductor die further comprising a second metallization structure on a bottom surface of the semiconductor structure, and wherein the one or more support structures comprise:
one or more first support structures on the first metallization structure; and
one or more second support structures on the second metallization structure.

15. The semiconductor die of claim 1, wherein the semiconductor structure comprises a wide bandgap semiconductor material, and wherein the wide bandgap semiconductor material is one of:
silicon carbide (SiC); or
a Group III-nitride.

16. The semiconductor die of claim 1, wherein the semiconductor die is arranged in a power semiconductor device package, and wherein the power semiconductor device package has a bond-line thickness (BLT) that is substantially equal to a height of the one or more support structures.

17. The semiconductor die of claim 16, wherein the semiconductor die is coupled to a submount in the power semiconductor device package with a die-attach material, the die-attach material at least partially contacting the one or more support structures, and
wherein the semiconductor die is coupled to the submount at an interface area, and the power semiconductor device package has a bond-line uniformity (BLU) that is substantially uniform across the interface area.

18. The semiconductor die of claim 1, wherein the semiconductor die is one of:
a metal-oxide-semiconductor field-effect transistor (MOSFET);
a Schottky diode; or
an insulated gate bipolar transistor (IGBT).

19. A power semiconductor device package, comprising:
a submount;
a semiconductor die on the submount, the semiconductor die comprising:
a semiconductor structure;
a metallization structure on a major surface of the semiconductor structure; and
one or more support structures on the metallization structure; and
a die-attach material around the one or more support structures between the semiconductor die and the submount, the die-attach material coupling the semiconductor die to the submount.

20. A method, comprising:
providing a semiconductor wafer comprising a semiconductor structure;
providing a metallization structure on a major surface of the semiconductor structure;
forming a plurality of support structures on the metallization structure; and
dicing the semiconductor wafer into a plurality of semiconductor die, each semiconductor die comprising at least one support structure.
